(19) United States
(12) Patent Application Publication
(10) Pub. No.: US 2026/0068447 A1
(43) Pub. Date: Mar. 5, 2026

(54) DISPLAY DEVICE AND METHOD OF MANUFACTURING THE SAME

(71) Applicant: Magnolia White Corporation, Tokyo (JP)

(72) Inventors: Hideyuki TAKAHASHI, Tokyo (JP); Yasuhito ARUGA, Tokyo (JP)

(73) Assignee: Magnolia White Corporation, Tokyo (JP)

(21) Appl. No.: 19/302,274

(22) Filed: Aug. 18, 2025

(30) Foreign Application Priority Data
Aug. 30, 2024 (JP) 2024-148515

(51) Int. Cl. H10K 59/124; H10K 59/12; H10K 59/122

(52) U.S. Cl. CPC H10K 59/124; H10K 59/1201; H10K 59/122

(57) ABSTRACT

According to one embodiment, a display device includes a first inorganic insulating layer disposed over an image display area and a peripheral area, a first metal layer disposed above the first inorganic insulating layer in the peripheral area, an organic insulating layer disposed in the image display area and the peripheral area, and having a first aperture overlapping the first metal layer, a second inorganic insulating layer covering the organic insulating layer and having a second aperture overlapping the first aperture, and a third inorganic insulating layer disposed above the second inorganic insulating layer and having a third aperture overlapping the second aperture.

### CROSS-REFERENCE TO RELATED APPLICATIONS

This application is based upon and claims the benefit of priority from Japanese Patent Application No. 2024-148515, filed Aug. 30, 2024, the entire contents of which are incorporated herein by reference.

### FIELD

Embodiments described herein relate generally to a display device and a method of manufacturing the same.

### BACKGROUND

In recent years, display devices in which organic light-emitting diodes (OLEDs) are applied as display elements have been put into practical use. Such display elements comprise a pixel circuit including a thin-film transistor, a lower electrode connected to the pixel circuit, an organic layer covering the lower electrode, and an upper electrode covering the organic layer. The organic layer includes functional layers such as a hole transport layer and an electron transport layer in addition to a light-emitting layer. In such display devices, a technology of suppressing degradation in reliability is required.

### BRIEF DESCRIPTION OF THE DRAWINGS

FIG. 1 is a diagram showing a configuration example of a display device according to one embodiment.

FIG. 2 is a plan view schematically showing an example of layout of subpixels.

FIG. 3 is a cross-sectional view schematically showing the display device taken along the line III-III in FIG. 2.

FIG. 4 is a plan view showing a configuration example of a region including a plurality of pads in the display device shown in FIG. 1.

FIG. 5 is a cross-sectional view schematically showing the display device taken along the line V-V in FIG. 4.

FIG. 6 is a cross-sectional view schematically showing the display device taken along the line VI-VI in FIG. 4.

FIG. 7 is a flowchart showing an example of a method of manufacturing the display device.

FIG. 8 is a cross-sectional view schematically showing a part of the method of manufacturing the display device.

FIG. 9 is a cross-sectional view schematically showing another part of the method of manufacturing the display device.

FIG. 10 is a cross-sectional view schematically showing still another part of the method of manufacturing the display device.

FIG. 11 is a cross-sectional view schematically showing still another part of the method of manufacturing the display device.

FIG. 12 is a cross-sectional view schematically showing still another part of the method of manufacturing the display device.

FIG. 13 is a cross-sectional view schematically showing still another part of the method of manufacturing the display device.

FIG. 14 is a flowchart showing another example of the method of manufacturing the display device.

FIG. 15 is a cross-sectional view schematically showing a part of the method of manufacturing the display device.

FIG. 16 is a cross-sectional view schematically showing another part of the method of manufacturing the display device.

FIG. 17 is a cross-sectional view schematically showing still another part of the method of manufacturing the display device.

FIG. 18 is a cross-sectional view schematically showing still another part of the method of manufacturing the display device.

FIG. 19 is a cross-sectional view schematically showing a display device according to a comparative example.

### DETAILED DESCRIPTION

In general, according to one embodiment, a display device includes a substrate, a first inorganic insulating layer disposed above the substrate and over an image display area that displays images and a peripheral area surrounding the image display area, a first metal layer disposed above the first inorganic insulating layer in the peripheral area, an organic insulating layer disposed in the image display area and the peripheral area, covering the peripheral portion of the first metal layer, and having a first aperture overlapping the first metal layer, a second inorganic insulating layer covering the organic insulating layer and having a second aperture overlapping the first aperture, and a third inorganic insulating layer disposed above the second inorganic insulating layer and having a third aperture overlapping the second aperture.

Further, according to another embodiment, a method of manufacturing the display device comprises forming a first metal layer above a first inorganic insulating layer disposed over a display area and a peripheral area surrounding the display area, in the peripheral area, forming an organic insulating layer which covers the peripheral portion of the first metal layer, and includes a first aperture overlapping the first metal layer, forming a second inorganic insulating layer which covers the organic insulating layer, forming a third inorganic insulating layer above the second inorganic insulating layer, and forming a second aperture overlapping the first aperture in the second inorganic insulating layer and a third aperture overlapping the second aperture in the third inorganic insulating layer by continuously etching the second inorganic insulating layer and the third inorganic insulating layer.

Furthermore, according to still another embodiment, a method of manufacturing the display device comprises forming a first metal layer above a first inorganic insulating layer disposed over a display area and a peripheral area surrounding the display area, in the peripheral area, forming an organic insulating layer which covers the peripheral portion of the first metal layer, and includes a first aperture overlapping the first metal layer, forming a second inorganic insulating layer which covers the organic insulating layer, forming a second aperture which overlaps the first aperture by etching the second inorganic insulating layer, forming a third inorganic insulating layer above the second inorganic insulating layer, after forming the second aperture, and forming a third aperture which overlaps the second aperture by etching the third inorganic insulating layer.

With configurations such as described above, it is possible to provide a display device which can suppress the decrease in reliability and a method of manufacturing the same.

An embodiment will now be described hereinafter with reference to the accompanying drawings. Note that the disclosure is merely an example, and proper changes within the spirit of the invention, which are easily conceivable by a skilled person, are included in the scope of the invention as a matter of course.

In addition, as to the drawings, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Further, viewing the constitutional elements parallel to the Z direction is referred to as plan view.

In the following description, the expression “overlapping” refers not only to cases where other elements overlap the target element from the third direction Z, but also to cases where other elements overlap the target element from the direction opposite to the third direction Z. Further, the expression “overlapping” refers not only to cases where the target elements are in direct contact with each other, but also to cases where the target elements are spaced apart or where other elements are located between the target elements.

The display device according to one embodiment is an organic electroluminescence display device comprising organic light-emitting diodes (OLEDs) as display elements, and may be incorporated into various electronic devices such as televisions, personal computers, in-vehicle devices, tablet terminals, smartphones, mobile phone terminals, and wearable devices.

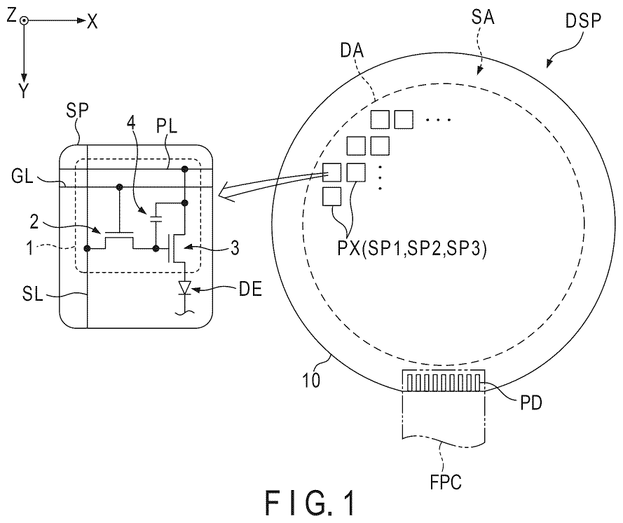

FIG. 1 is a diagram showing a configuration example of a display device DSP according to this embodiment. The display device DSP comprises an insulating substrate 10. The substrate 10 has a display area DA that displays images and a peripheral area SA surrounding the display area DA. The substrate 10 may be glass or a flexible resin film.

In this embodiment, the shapes of the substrate 10 and the display area DA in plan view are circular. Note but that the shapes of the substrate 10 and the display area DA in plan view are not limited to circular, and may as well be some other shape such as rectangular, square, or elliptical.

The display area DA includes a plurality of pixels PX arranged in a matrix along the first direction X and the second direction Y. Each of the pixels PX includes a plurality of subpixels SP that display different colors. In this embodiment, such a case is assumed that the pixels PX each include a blue subpixel SP1, a green subpixel SP2, and a red subpixel SP3. The pixels PX each may as well include subpixels SP of some other color such as white in addition to the subpixels SP1, SP2, and SP3, or in place of any one of the subpixels SP1, SP2, and SP3.

The subpixels SP each comprises a pixel circuit 1 and a display element DE driven by the pixel circuit 1. The pixel circuit 1 comprises a pixel switch 2, a drive transistor 3, and a capacitor 4. The pixel switch 2 and drive transistor 3 are switching elements configured, for example, by thin-film transistors.

In the display area DA, there are a plurality of scanning lines GL that supply scanning signals to the pixel circuits 1 of the subpixels SP, a plurality of signal lines SL that supply image signals to the pixel circuits 1 of the subpixels SP, and a plurality of power supply lines PL. In the example shown in FIG. 1, the scanning lines GL and power supply lines PL extend along the first direction X, and the signal lines SL extend along the second direction Y.

The gate electrode of the pixel switch 2 is connected to the respective scanning line GL. One of the source electrode and drain electrode of the pixel switch 2 is connected to the respective signal line SL, and the other is connected to the gate electrode of the drive transistor 3 and the capacitor 4.

In the drive transistor 3, one of the source electrode and drain electrode is connected to the respective power supply line PL and the capacitor 4, and the other is connected to the display element DE. Note that the configuration of the pixel circuit 1 is not limited to that of the example presented here. For example, the pixel circuit 1 may include more thin-film transistors and capacitors.

The display device DSP further includes a plurality of pads PD in the peripheral area SA. The pads PD constitute, for example, pads for a touch panel. Each of the pads PD extends along the second direction Y, but the configuration is not limited to this. For example, some of the pads PD may extend in a diagonal direction. The pads PD are each formed by, for example, multiple metal layers, which will be described later.

The pads PD with such a configuration are electrically connected to a flexible printed circuit board FPC, for example, indicated by an alternate long and short dash line.

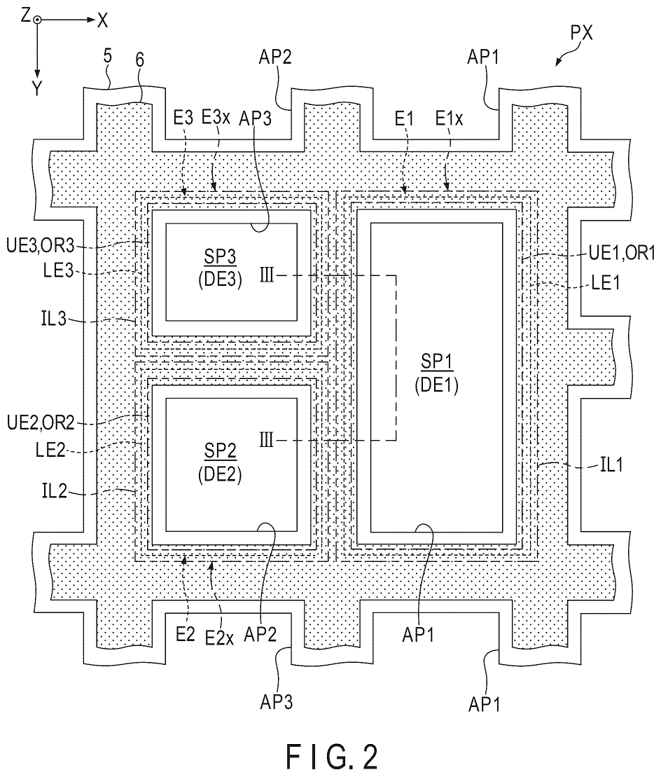

FIG. 2 is a plan view schematically showing an example of the layout of the subpixels SP1, SP2, and SP3. In the example shown in FIG. 2, the subpixels SP2 and SP3 are arranged along the subpixel SP1 in the first direction X. Further, the subpixels SP2 and SP3 are arranged along the second direction Y.

When the subpixels SP1, SP2, and SP3 are arranged in such a layout, a column in which the subpixels SP2 and SP3 are alternately arranged along the second direction Y, and a column in which multiple subpixels SP1 are repeatedly arranged along the second direction Y are formed in the display area DA. These columns are arranged alternately along the first direction X. Note that the layout of the subpixels SP1, SP2, and SP3 is not limited to that of the example shown in FIG. 2.

In the display area DA, a rib layer 5 is disposed. In this embodiment, the rib layer 5 corresponds to the third inorganic insulating layer.

The rib layer 5 has pixel apertures AP1, AP2, and AP3 in the subpixels SP1, SP2, and SP3, respectively. In the example shown in FIG. 2, the pixel aperture AP1 is larger than the pixel aperture AP2, and the pixel aperture AP2 is larger than the pixel aperture AP3.

That is, among the subpixels SP1, SP2, and SP3, the aperture ratio of the subpixel SP1 is the largest, and the aperture ratio of the subpixel SP3 is the smallest. Note that the sizes of the pixel apertures AP1, AP2, and AP3 are not limited to those of this example. For example, at least two of the pixel apertures AP1, AP2, and AP3 may have the same size.

The subpixel SP1 comprises a lower electrode LE1, an upper electrode UE1, and an organic layer OR1, each overlapping the pixel aperture AP1. The subpixel SP2 comprises a lower electrode LE2, an upper electrode UE2, and an organic layer OR2, each overlapping the pixel aperture AP2. The subpixel SP3 includes a lower electrode LE3, an upper electrode UE3, and an organic layer OR3, each overlapping the pixel aperture AP3.

The portions of the lower electrode LE1, upper electrode UE1, and organic layer OR1, which overlap the pixel aperture AP1 constitute a display element DE1 of the subpixel SP1. The portions of the lower electrode LE2, upper electrode UE2, and organic layer OR2, which overlap the pixel aperture AP2 constitute a display element DE2 of the subpixel SP2. The portions of the lower electrode LE3, upper electrode UE3, and organic layer OR3, which overlap the pixel aperture AP3 constitute a display element DE3 of the subpixel SP3. The display elements DE1, DE2, and DE3 may further include a cap layer, which will be described later. The rib layer 5 surrounds each of the display elements DE1, DE2, and DE3.

In the display area DA, a partition 6 is disposed. The partition 6 is located above the rib layer 5 and entirely overlaps the rib layer 5. In the example shown in FIG. 2, the partition 6 has a planar shape similar to that of the rib layer 5. That is, the partition 6 has apertures in locations corresponding to the subpixels SP1, SP2, and SP3, respectively.

From another perspective, the rib layer 5 and partition 6 have a grid pattern in plan view, enclosing each of the display elements DE1, DE2, and DE3. The partition 6 encloses the pixel apertures AP1, AP2, and AP3. The partition 6 serves as wiring for supplying a common voltage to the upper electrodes UE1, UE2, and UE3.

In this embodiment, below the lower electrodes LE1, LE2, and LE3, inorganic insulating layers IL1, IL2, and IL3 are disposed, respectively.

In the example shown in FIG. 2, the inorganic insulating layers IL1, IL2, and IL3 are spaced apart from each other.

The inorganic insulating layers IL1, IL2, and IL3 each have an outer shape that is slightly larger than that of the lower electrodes LE1, LE2, and LE3. That is, an end portion E1x of the inorganic insulating layer IL1 protrudes from an end portion E1 of the lower electrode LE1 over the entire circumference.

Similarly, an end portion E2x of the inorganic insulating layer IL2 protrudes from an end portion E2 of the lower electrode LE2 over the entire circumference. An end portion E3x of the inorganic insulating layer IL3 protrudes from an end portion E3 of the lower electrode LE3 over the entire circumference.

Note that the shapes of the inorganic insulating layers IL1, IL2, and IL3 are not limited to those of the examples shown in FIG. 2. For example, parts of the inorganic insulating layers IL1, IL2, and IL3 may be connected. Or, parts of the end portions E1x, E2x, and E3x may overlap the lower electrodes LE1, LE2, and LE3, respectively.

The lower electrodes LE1, LE2, and LE3 are connected to the pixel circuits 1 (more specifically, the drain electrodes of the drive transistors 3 shown in FIG. 1) of the subpixels SP1, SP2, and SP3, respectively, through contact holes not shown. The contact holes not shown all overlap the rib layer 5 and the partition 6.

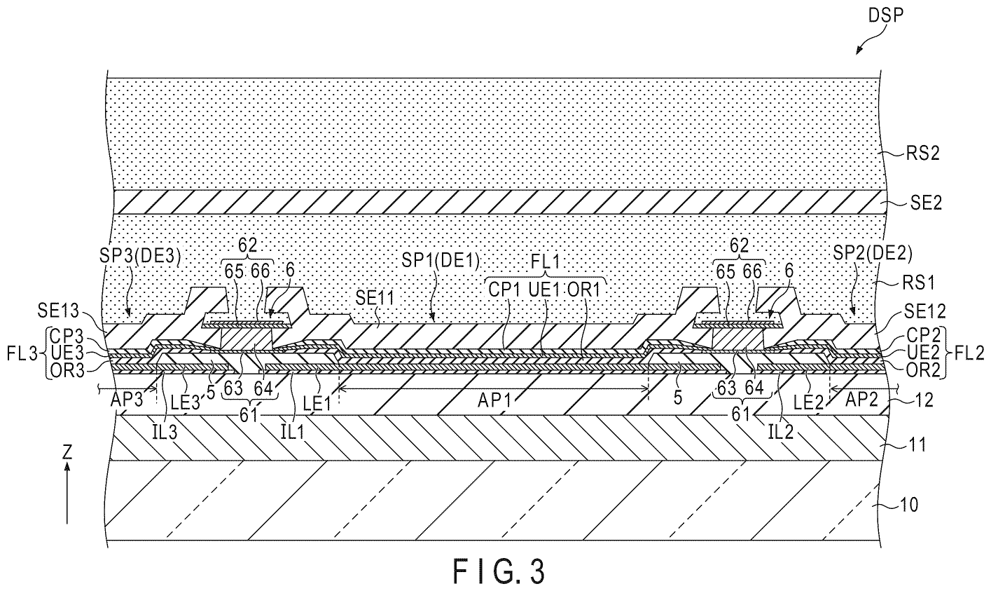

FIG. 3 is a cross-sectional view schematically showing the display device DSP taken along the line III-III in FIG. 2. The circuit layer 11 is disposed on the substrate 10 described above. The circuit layer 11 includes various circuits and wiring lines such as the pixel circuits 1, scanning lines GL, signal lines SL, and power supply lines PL shown in FIG. 1. The circuit layer 11 is covered by an organic insulating layer 12. The organic insulating layer 12 functions as a planarization film to planarize the unevenness caused by the circuit layer 11.

The inorganic insulating layers IL1, IL2, and IL3 are disposed on the organic insulating layer 12. The lower electrodes LE1, LE2, and LE3 are respectively disposed on the inorganic insulating layers IL1, IL2, and IL3. That is, the inorganic insulating layers IL1, IL2, and IL3 are disposed between the organic insulating layer 12 and the lower electrodes LE1, LE2, and LE3 in the display area DA.

The rib layer 5 is disposed on the organic insulating layer 12 and the lower electrodes LE1, LE2, and LE3. The end portions of the lower electrodes LE1, LE2, and LE3 (end portions E1, E2, and E3 shown in FIG. 2) and the end portions of the inorganic insulating layers IL1, IL2, and IL3 (end portions E1x, E2x, and E3x shown in FIG. 2) are all covered by the rib layer 5.

The partition 6 includes a conductive lower portion 61 disposed on the rib layer 5 and an upper portion 62 disposed on the lower portion 61. The upper portion 62 has a width greater than that of the lower portion 61. With this configuration, both end portions of the upper portion 62 protrude beyond the side surfaces of the lower portion 61. That is, the partition 6 has an overhanging shape in which both end portions of the upper portion 62 protrude beyond the side surfaces of the lower portion 61.

In the example shown in FIG. 3, the lower portion 61 has a bottom layer 63 and an axis layer 64. The bottom layer 63 is located between the axis layer 64 and the rib layer 5. Further, in the example shown in FIG. 3, the upper portion 62 has a first top layer 65 and a second top layer 66. The first top layer 65 is disposed on the axis layer 64. The second top layer 66 is disposed on the first top layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portion 61 of the partition 6.

The display element DE1 includes a cap layer CP1 that covers the upper electrode UE1. The display element DE2 includes a cap layer CP2 that covers the upper electrode UE2. The display element DE3 includes a cap layer CP3 that covers the upper electrode UE3. The cap layers CP1, CP2, and CP3 serve as optical adjustment layers to improve the light extraction efficiency of the light emitted from the organic layers OR1, OR2, and OR3, respectively.

In the following description, the stacked layer body constituted by the organic layer OR1, the upper electrode UE1, and the cap layer CP1 is referred to as a stacked layer film FL1, the stacked layer body constituted by the organic layer OR2, the upper electrode UE2, and the cap layer CP2 is referred to as a stacked layer film FL2, and the stacked layer body constituted by the organic layer OR3, the upper electrode UE3, and the cap layer CP3 is referred to as a stacked layer film FL3.

In the subpixels SP1, SP2, and SP3, sealing layers SE11, SE12, and SE13 are disposed to cover the stacked layer films FL1, FL2, and FL3, respectively.

Specifically, the sealing layer SE11 continuously covers the partition 6 surrounding the cap layer CP1 and the subpixels SP1. The sealing layer SE12 continuously covers the partition 6 surrounding the cap layer CP2 and the subpixels SP2. The sealing layer SE13 continuously covers the partition 6 surrounding the cap layer CP3 and the subpixels SP3.

In the example shown in FIG. 3, the sealing layer SE11 on the partition 6 between the subpixels SP1 and SP2 is spaced apart from the sealing layer SE12 on the partition 6. Further, the sealing layer SE11 on the partition 6 between the subpixels SP1 and SP3 is spaced apart from the sealing layer SE13 on the partition 6. Note here that any two of the sealing layers SE11, SE12, and SE13 may come into contact with each other above the partition 6.

For example, between the sealing layers SE11, SE12, and SE13 and the upper portion 62 of the partition 6, gaps are formed. At least portions of these gaps may be filled with the stacked layer films FL1, FL2, and FL3, respectively.

The sealing layers SE11, SE12, and SE13 are covered by a resin layer RS1. The resin layer RS1 is covered by a sealing layer SE2. The sealing layer SE2 is covered by a resin layer RS2. The resin layers RS1, RS2, and the sealing layer SE2 are continuously provided over at least the entire display area DA and a portion thereof extends over to the peripheral area SA.

A cover member such as a polarizer, protective film, or cover glass may be further disposed above the resin layer RS2. Such a cover member may be adhered to the resin layer RS2 via an adhesive layer such as an optical clear adhesive (OCA). Further, above the display elements DE1, DE2, and DE3, color filters corresponding to the colors of the subpixels SP1, SP2, and SP3 may be provided, respectively.

The organic insulating layer 12 is formed from an organic insulating material such as polyimide. The inorganic insulating layers, IL1, IL2, and IL3, the rib layer 5 and the sealing layers SE11, SE12, SE13, and SE2 are formed, for example, from inorganic insulating materials such as silicon nitride (SiNx), silicon oxide (SiOx), and silicon oxynitride (SiON).

The inorganic insulating layers, IL1, IL2, and IL3 are formed of an inorganic insulating material different from that of the rib layer 5, for example. In one example, the inorganic insulating layers, IL1, IL2, and IL3 are formed of silicon nitride, the rib layer 5 is formed of silicon nitride, and the sealing layers SE11, SE12, SE13, and SE2 are formed of silicon nitride. The resin layers RS1 and RS2 are formed of a resin material (organic insulating material) such as epoxy resin or acrylic resin.

The lower electrodes LE1, LE2, and LE3 are each a stacked layer body containing a transparent electrode formed from an oxide conductive material such as ITO and a metal electrode formed from a metal material such as silver. The upper electrodes UE1, UE2, and UE3 are formed from a metal material such as a magnesium-silver alloy (MgAg). For example, the lower electrodes LE1, LE2, and LE3 correspond to the anodes, and the upper electrodes UE1, UE2, and UE3 correspond to the cathodes.

The organic layers OR1, OR2, and OR3 are constituted by multiple thin films including a light-emitting layer. For example, the organic layers OR1, OR2, and OR3 have a structure in which a hole injection layer, a hole transport layer, an electron blocking layer, an emissive layer, a hole blocking layer, an electron transport layer, and an electron injection layer are sequentially stacked along the third direction Z. Note here that the organic layers OR1, OR2, and OR3 may as well have some other structure, such as the so-called tandem structure including multiple light-emitting layers.

The cap layers CP1, CP2, and CP3 have, for example, a stacked layer structure in which multiple transparent layers are stacked one on another. These transparent layers may include a layer formed from an inorganic material and a layer formed from an organic material. Further, these transparent layers have different refractive indices. For example, the refractive indices of these transparent layers are different from the refractive indices of the upper electrodes UE1, UE2, UE3 and those of the sealing layers SE11, SE12, SE13. Note that at least one of the cap layers CP1, CP2, CP3 may be omitted.

To the partition 6, a common voltage is supplied. This common voltage is supplied to each of the upper electrodes UE1, UE2, and UE3, which are in contact with the lower portion 61. To the lower electrodes LE1, LE2, and LE3, pixel voltages corresponding to the video signals of the signal lines SL are supplied through the pixel circuits 1 of the subpixels SP1, SP2, and SP3, respectively.

The organic layers OR1, OR2, and OR3 emit light according to the applied voltage. Specifically, when a potential is created between the lower electrode LE1 and the upper electrode UE1, the light-emitting layer of the organic layer OR1 emits light in a blue wavelength band. When a potential is created between the lower electrode LE2 and the upper electrode UE2, the light-emitting layer of the organic layer OR2 emits light in a green wavelength band. When a potential is created between the lower electrode LE3 and the upper electrode UE3, the light-emitting layer of the organic layer OR3 emits light in a red wavelength band.

As another example, the light-emitting layers of the organic layers OR1, OR2, and OR3 may emit light of the same color (for example, white). In this case, the display device DSP may comprise color filters that convert the light emitted by the light-emitting layers into light of colors corresponding to the subpixels SP1, SP2, and SP3. Further, the display device DSP may as well comprise a layer containing quantum dots that generate light of colors corresponding to the subpixels SP1, SP2, and SP3 when excited by the light emitted by the light-emitting layers.

The bottom layer 63 and the axis layer 64 are formed, for example, from a metal material. As the metal material for the bottom layer 63, for example, molybdenum (Mo), titanium (Ti), titanium nitride (TiN), molybdenum-tungsten alloy (MoW), or molybdenum-niobium alloy (MoNb) may be used. As the metal material for the axis layer 64, for example, aluminum (Al), aluminum-neodymium alloy (AlNd), aluminum-yttrium alloy (AlY), or aluminum-silicon alloy (AlSi) may be used. Note here that at least one of the bottom layer 63 and the axis layer 64 may have a stacked layer structure containing multiple layers. Additionally, the axial layer 64 may include a layer formed from an insulating material. Furthermore, it may have a single-layer structure in which the lower portion 61 is formed from a conductive material.

For example, the first top layer 65 is formed from a metal material, and the second top layer 66 is formed from a transparent conductive oxide. As the metal material of the first top layer 65, for example, titanium, titanium nitride, molybdenum, tungsten, molybdenum-tungsten alloy, or molybdenum-niobium alloy may be used. As the conductive oxide of the second top layer 66, for example, indium tin oxide (ITO), indium zinc oxide (IZO), or indium gallium zinc oxide (IGZO) can be used. Note that the upper portion 62 may have a single-layer structure formed from a specific material. Furthermore, the upper portion 62 may include a layer formed from an insulating material.

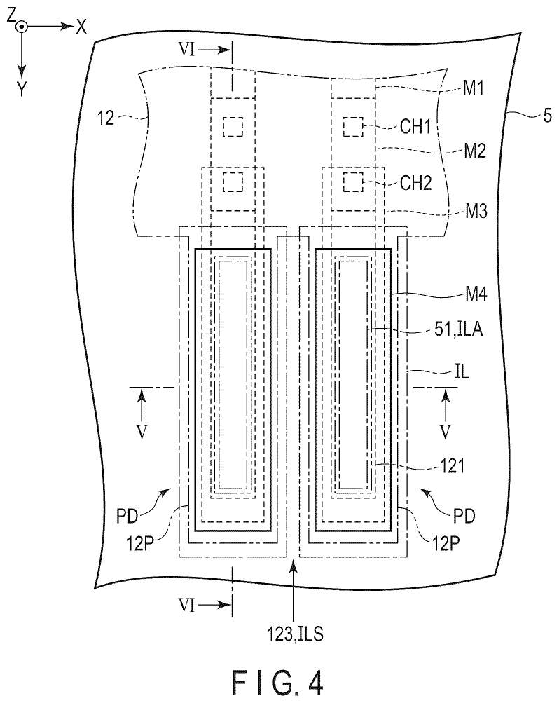

FIG. 4 is a plan view showing a configuration example of a region including the pads PD of the display device DSP shown in FIG. 1. In FIG. 4, the display area DA is formed in the upper portion of the figure.

The pads PD are arranged along the first direction X and extend along the second direction Y as shown in FIG. 4. The rib layer 5 and the organic insulating layer 12 are arranged not only in the display area DA but also in the peripheral area SA including the pads PD.

Further, the multiple inorganic insulating layers IL are disposed in the peripheral area SA. The inorganic insulating layers IL are formed using the same material and the same manufacturing process as those of the inorganic insulating layers IL1, IL2, and IL3 in the display area DA. In this embodiment, the inorganic insulating layers IL, IL1, IL2, and IL3 correspond to the second inorganic insulating layer.

The rib layer 5 has apertures 51 (third apertures) each overlapping the respective pad PD, as shown in FIG. 4. The organic insulating layer 12 has apertures 121 (first apertures) each overlapping the respective pad PD, as shown in FIG. 4. The multiple inorganic insulating layers IL have apertures ILA (second apertures) overlapping the pads PD, respectively.

These apertures 51, 121, and IL overlap the respective one of the pads PD. In other words, the aperture 51 overlaps the aperture IL, and the aperture IL overlaps the aperture 121.

The apertures 51, 121, and ILAs extend in a direction different from the direction in which the pads PD are arranged. The apertures 51, 121, and ILA extend, for example, along the second direction Y. Specifically, the apertures 51, 121, and ILAs have a rectangular shape elongated along the second direction Y.

In the example shown in FIG. 4, the area of the aperture 121, in plan view, is larger than the areas of the apertures 51 and ILA. The edge of the aperture 121 is located on an outer side of the edges of the apertures 51 and ILA. With this configuration, the organic insulating layer 12 is not exposed from the aperture 51 and ILA.

The organic insulating layer 12 has a plurality of protrusions 12P overlapping the pads PD, respectively. From another perspective, the organic insulating layer 12 has slits 123. The slits 123 are each formed between each respect adjacent pair of pads PD (protrusions 12P).

The inorganic insulating layers IL are formed to cover the protrusions 12P, respectively. The width of the inorganic insulating layers IL along the first direction X is greater than the width of the protruding portions 12P along the first direction X. Further, each pair of inorganic insulating layers IL adjacent to each other along the first direction X are spaced apart from each other between the respective adjacent pair of pads PD. In other words, the slits ILS are each formed between each respective adjacent pair of inorganic insulating layers IL.

The slits ILS overlap the slits 123 of the organic insulating layer 12, respectively. The width of the slits ILS along the first direction X is smaller than the width of the slits 123 along the first direction X, for example.

The slits 123 and ILS extend along the second direction Y. The slits 123 and ILS are arranged along the first direction X, while interposing the respective pad PD between the respective adjacent pair of slits. The slits 123 and ILS are opened toward the end portion of the substrate 10 (shown in FIG. 1).

The display device DSP further includes a plurality of metal layers M1, M2, M3, and M4, as shown in FIG. 4. In FIG. 4, two of these metal layers M1, M2, M3, and M4 arranged along the first direction X are shown. In this embodiment, the metal layer M3 corresponds to the first metal layer, and the metal layer M4 corresponds to the second metal layer.

Each of the metal layers M1, M2, M3, and M4 extends along the second direction Y. Each adjacent pair of the metal layers M1, M2, M3, and M4 are arranged at an interval along the first direction X. The pads PD are each formed by the metal layers M3 and M4.

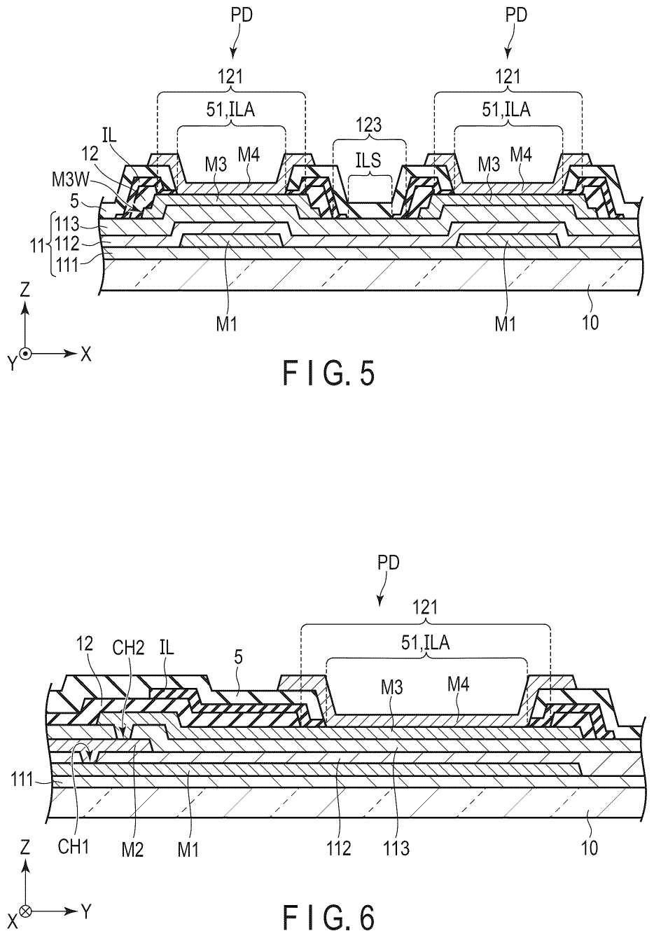

FIG. 5 is a cross-sectional view schematically showing the display device DSP taken along the line V-V in FIG. 4. FIG. 6 is a cross-sectional view schematically showing the display device DSP taken along the line VI-VI in FIG. 4.

As described above, the display device DSP includes a circuit layer 11. The circuit layer 11 is disposed above the substrate 10, over the display area DA and the peripheral area SA. The circuit layer 11 includes inorganic insulating layers 111, 112, and 113. In this embodiment, the inorganic insulating layer 113 corresponds to the first inorganic insulating layer. The metal layers M1 and M2 described above constitute the circuit layer 11 together with the inorganic insulating layers 111, 112, and 113.

The inorganic insulating layer 111 is disposed on the substrate 10. The metal layer M1 is disposed on the inorganic insulating layer 111. The metal layer M1 is formed in the same layer as that of the scanning lines GL, for example. The inorganic insulating layer 112 is disposed on the inorganic insulating layer 111 and the metal layer M1. The inorganic insulating layer 112 has a contact hole CH1, as shown in FIG. 6.

The metal layer M2 is disposed on the inorganic insulating layer 112, as shown in FIG. 6. From another perspective, the metal layer M1 is disposed between the substrate 10 and the metal layer M2. The metal layer M2 is formed in the same layer as that of the signal lines SL, for example. The metal layer M2 is electrically connected to the metal layer M1 via the contact hole CH1. The metal layer M2 extends toward the display area DA.

The inorganic insulating layer 113 is disposed on the inorganic insulating layer 112 and the metal layer M2. The metal layer M2 is disposed between the substrate 10 and the inorganic insulating layer 113. The inorganic insulating layer 113 has a contact hole CH2.

The metal layer M3 is located directly above the metal layer M1 in the peripheral area SA and is disposed on inorganic insulating layer 113. The metal layer M3 is electrically connected to the metal layer M2. Specifically, the metal layer M3 is brought into contact with the metal layer M2 via the contact hole CH2.

The organic insulating layer 12 is disposed on the inorganic insulating layer 113 and the metal layer M3. The organic insulating layer 12 covers the peripheral portion of the metal layer M3, over its entire circumference as shown in FIGS. 5 and 6.

The inorganic insulating layer IL is disposed on the inorganic insulating layer 113, the metal layer M3, and the organic insulating layer 12. The inorganic insulating layer IL covers the organic insulating layer 12, as shown in FIGS. 5 and 6. Note that a part of the organic insulating layer 12 is exposed from the inorganic insulating layer IL.

The peripheral portion of the organic insulating layer 12 is not exposed from the inorganic insulating layer IL in the protruding portion 12P. From another perspective, the inorganic insulating layer IL is brought into contact with the metal layer M3 in the aperture 121, as shown in FIG. 5, and is brought into contact with the inorganic insulating layer 113 in an outer side of the aperture 121 (for example, between adjacent pads PD). The inorganic insulating layer 113 is exposed from the inorganic insulating layer IL between each adjacent pair of pads PD (slits ILS) as shown in FIG. 5.

The rib layer 5 is disposed on the organic insulating layer 12 and the inorganic insulating layers 113 and IL. The rib layer 5 has a thickness greater than that of the inorganic insulating layer IL. The rib layer 5 is brought into contact with the inorganic insulating layer 113 between each adjacent pair of pads PD.

In other words, the inorganic insulating layer 113 is covered by the rib layer 5 in the slits ILS. The metal layer M3 is exposed through the aperture 121 of the organic insulating layer 12, the aperture IL of the inorganic insulating layer IL, and the aperture 51 of the rib layer 5.

The metal layer M4 is disposed on the metal layer M3 and the rib layer 5. The metal layer M4 is electrically connected to the metal layer M3 through the aperture 121 of the organic insulating layer 12, the aperture 51 of the rib layer 5, and the aperture IL of the inorganic insulating layer IL. The metal layer M4 overlaps the peripheral portion of the aperture 51 of the rib layer 5.

The inorganic insulating layers 111, 112, and 113 are formed from one of silicon oxide, silicon nitride, and silicon oxynitride. The metal layers M2, M3, and M4 are each formed from multiple layers, for example. In one example, they include two titanium layers formed from a titanium-based material and an aluminum layer formed from an aluminum-based material placed between the two titanium layers. Further, at least one of the metal layers M2, M3, and M4 may be formed by arranging an aluminum layer between layers formed from a molybdenum-based material.

Next, a method of manufacturing the pads PD in the display device DSP will be described.

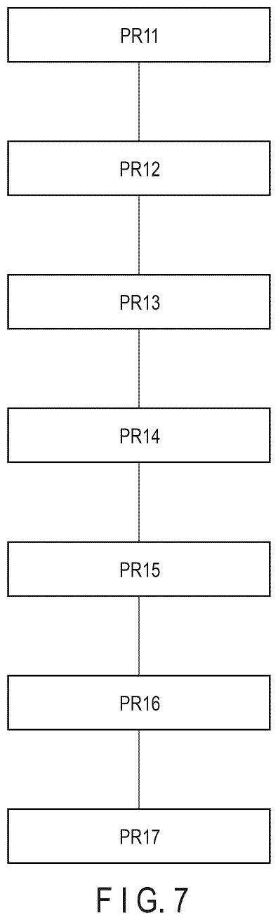

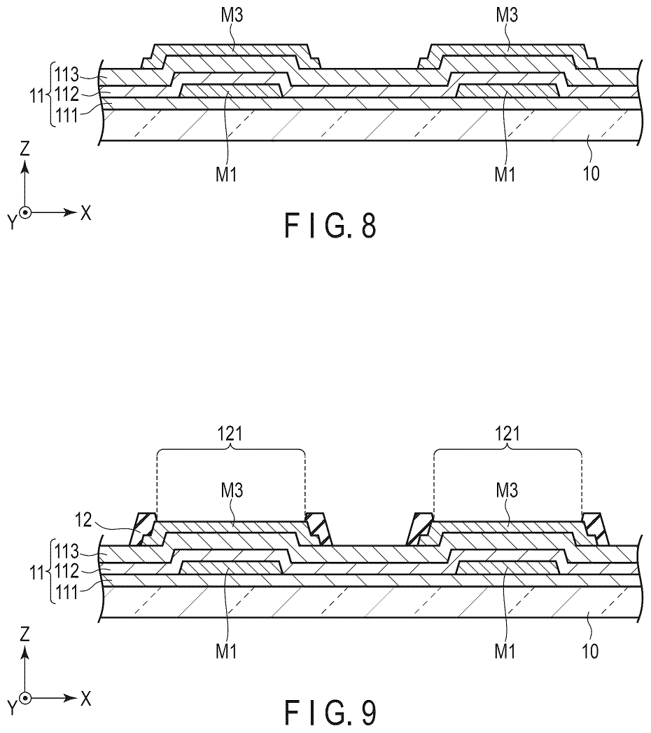

FIG. 7 is a flowchart illustrating an example of the manufacturing method of the display device DSP. FIGS. 8 to 13 are each a cross-sectional view schematically illustrating a part of the manufacturing method of the display device DSP. In FIGS. 8 to 13, the peripheral area SA is shown.

In the manufacturing of the display device DSP, first, as shown in FIG. 8, a metal layer M3 is formed on the inorganic insulating layer 113 (processing step PR11). After the processing step PR11, as shown in FIG. 9, an organic insulating layer 12 is formed on the metal layer M3 (processing step PR12). The organic insulating layer 12 covers the peripheral portion of the metal layer M3. Further, the organic insulating layer 12 has an aperture 121 that overlaps the metal layer M3.

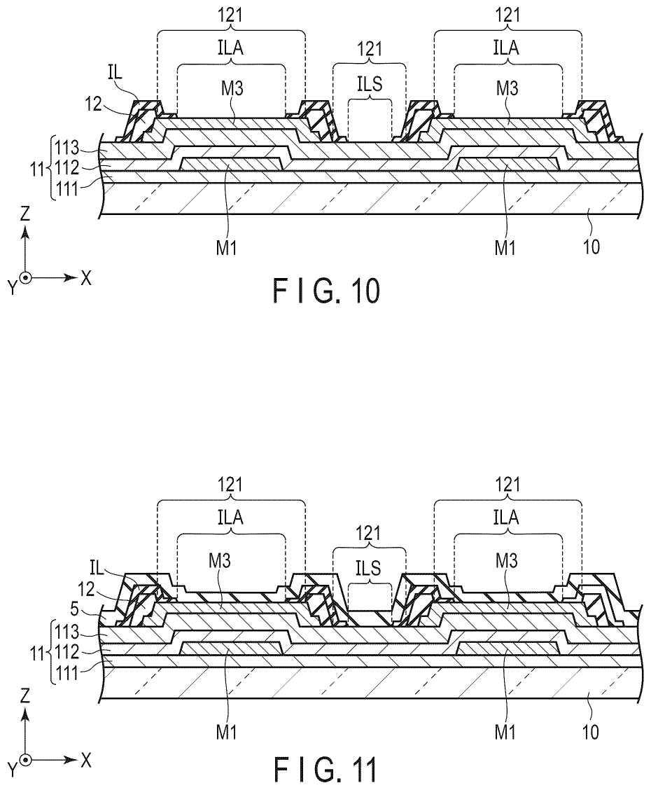

After the processing step PR12, an inorganic insulating layer IL is formed to cover the organic insulating layer 12 (processing step PR13), and the inorganic insulating layer IL is subjected to an etching (dry etching), thus forming the aperture ILA and the slit ILS as shown in FIG. 10 (processing step PR14). The aperture ILAs overlaps the aperture 121. After the processing step PR14, the metal layer M3 is exposed through the aperture ILA.

After the processing step PR14, as shown in FIG. 11, a rib layer 5 is formed on the inorganic insulating layer IL (processing step PR15). The rib layer 5 is in contact with the metal layer M3 through the aperture ILA. Further, the rib layer 5 is in contact with the inorganic insulating layer 113 through the slit ILS.

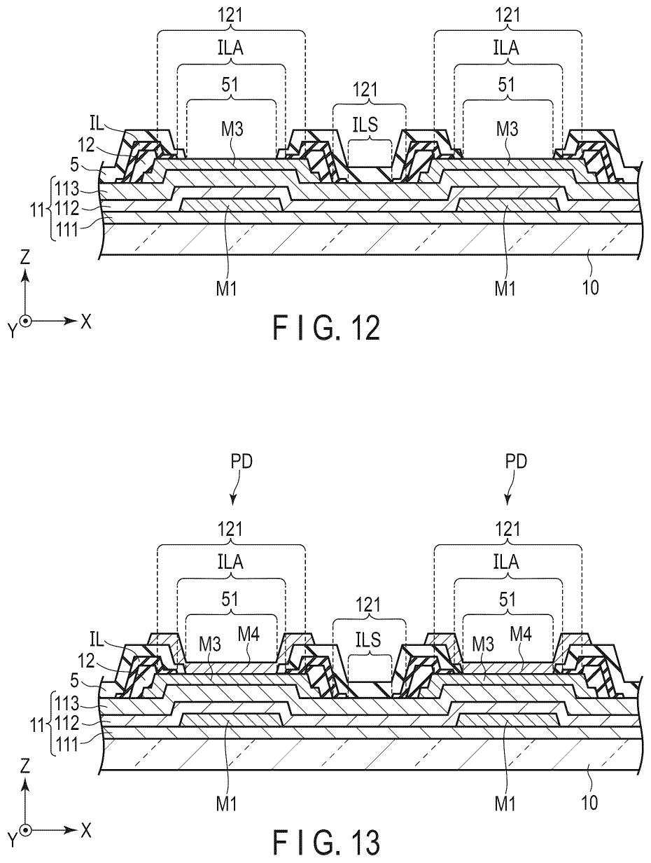

After the processing step PR15, the rib layer 5 is subjected to etching (dry etching), thus forming the aperture 51 as shown in FIG. 12 (processing step PR16). After the processing step PR16, the metal layer M3 is exposed through the aperture 51.

After the processing step PR16, as shown in FIG. 13, a metal layer M4 is formed on the metal layer M3 and the rib layer 5 (processing step PR17). With this configuration, the pads PD can be formed in the peripheral area SA. In the case of this manufacturing method, the aperture 51 may be offset relative to the aperture ILA, as shown in the example in FIG. 12.

Next, another example of the method of manufacturing the pads PD in the display device DSP will be explained.

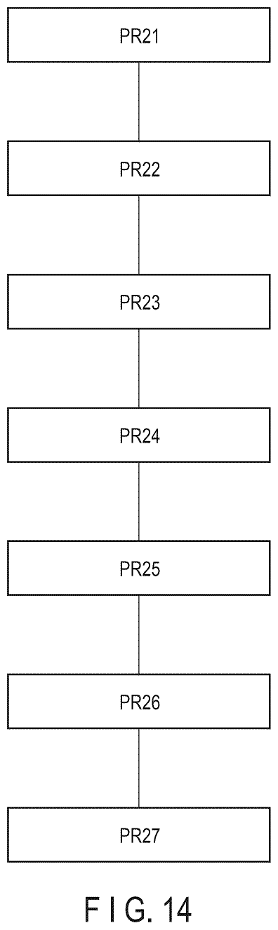

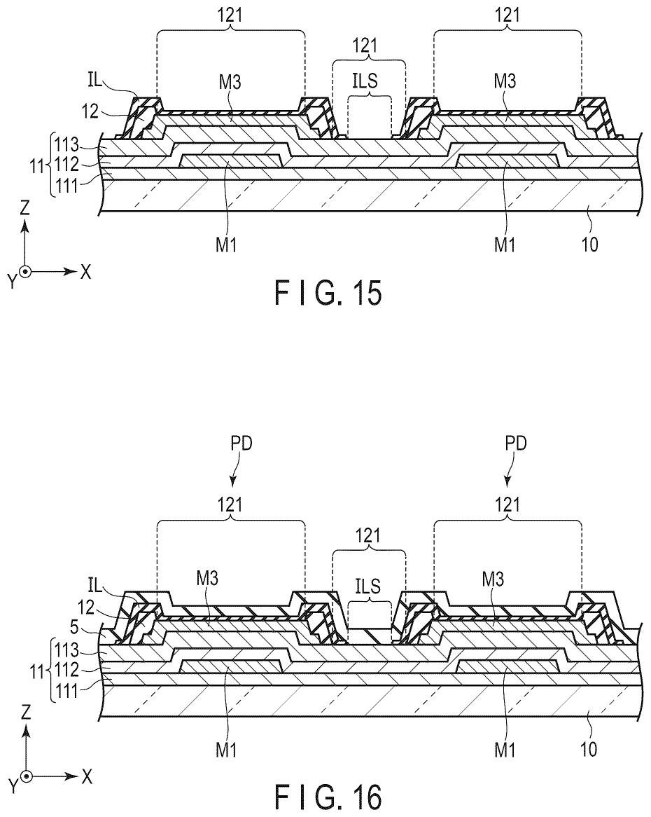

FIG. 14 is a flowchart showing another example of the manufacturing method for the display device DSP. FIGS. 15 to 18 are cross-sectional views each schematically showing a part of the manufacturing method for the display device DSP. In FIGS. 15 to 18, the peripheral area SA is shown.

In the manufacturing of the display device DSP, first, a metal layer M3 is formed on the inorganic insulating layer 113 (processing step PR21), and then an organic insulating layer 12 is formed on the metal layer M3 (processing step PR22). In processing steps PR21 and PR22, shapes similar to those described with reference to FIGS. 8 and 9 can be obtained, respectively.

After the processing step PR22, an inorganic insulating layer IL covering the organic insulating layer 12 is formed (processing step PR23), as shown in FIG. 15. After the processing step PR23, the inorganic insulating layer IL is brought into contact with the metal layer M3 through the aperture 121 of the organic insulating layer 12. After the processing step PR23, the inorganic insulating layer IL is subjected to etching (dry etching), thereby forming a slit ILS (processing step PR24).

After the processing step PR24, as shown in FIG. 16, a rib layer 5 is formed on the inorganic insulating layers 113 and IL (processing step PR25). On the metal layer M3, the inorganic insulating layer IL and the rib layer 5 are stacked in the aperture 121.

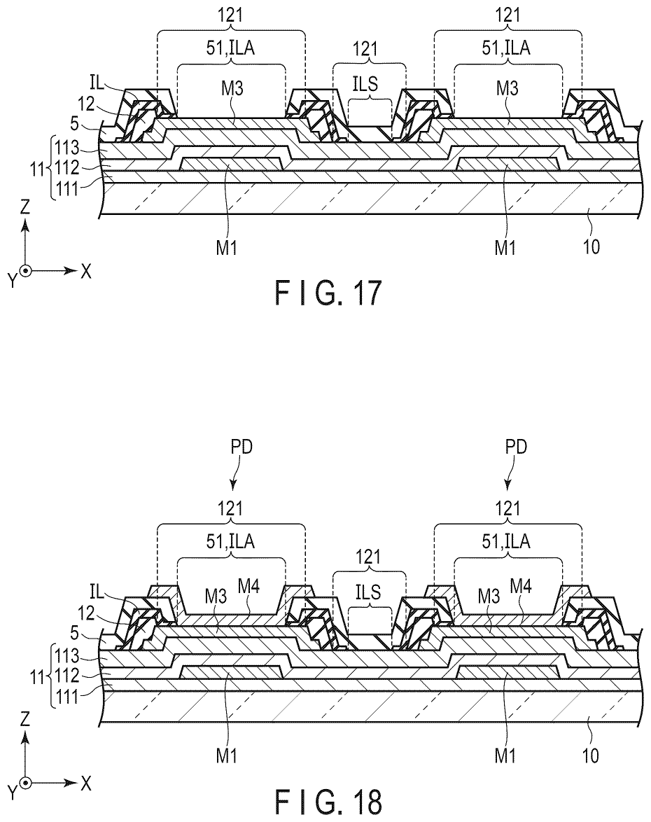

After the processing step PR25, etching (dry etching) is continuously performed on the inorganic insulating layer IL and the rib layer 5, thereby forming the apertures 51 and ILA as shown in FIG. 17 (processing step PR26).

In other words, the apertures 51 and ILA are formed in one step by etching. After the processing step PR26, the metal layer M3 is exposed through the apertures 51 and ILA. After the processing step PR26, as shown in FIG. 18, a metal layer M4 is formed on the metal layer M3 and the rib layer 5 (processing step PR27). With this configuration, the pads PD can be formed in the peripheral area SA. In the case of this manufacturing method, the aperture 51 is not likely to shift relative to the aperture ILA, as shown in the example in FIG. 18. In the case of this manufacturing method, the size of the aperture 51 is equivalent to that of the aperture ILAs, as shown in the example in FIG. 18. In other words, the edge of the aperture 51 are substantially aligned with the edge of the aperture ILA.

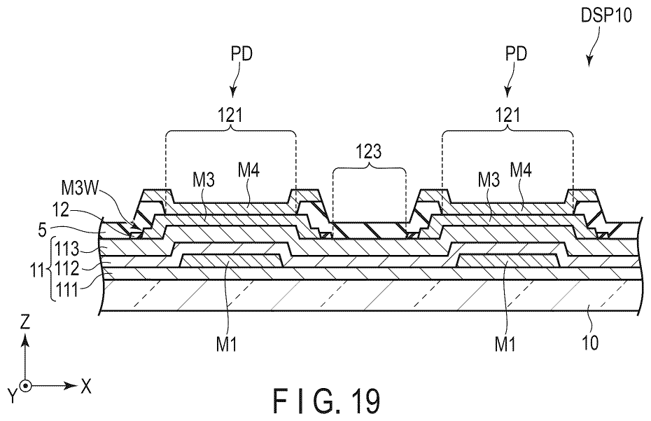

FIG. 19 is a cross-sectional view schematically showing a display device DSP10 according to a comparative example. The display device DSP10 according to the comparative example is different from the display device DSP according to the present embodiment in that a layer corresponding to the inorganic insulating layer IL is not formed in the peripheral area SA.

In the display device DSP10, after forming the organic insulating layer 12 in the peripheral area SA, during the etching process of the inorganic insulating layers IL1, IL2, and IL3 in the display area DA, the organic insulating layer 12 in the peripheral area SA may be scraped off.

When the organic insulating layer 12 is scraped off, the side walls M3W of the metal layer M3 are easily exposed from the organic insulating layer 12, as shown in FIG. 19. The side walls M3W are included in the peripheral area of the metal layer M3. When the aluminum layer is exposed from the side walls M3W of the metal layer M3, there is a risk that silver (Ag) may precipitate near the metal layer M3 during the processing step of forming the lower electrodes LE1, LE2, and LE3.

Since the silver thus deposited is a foreign substance, the contact resistance between the metal layer M3 and the metal layer M4 increases. As a result, there is a risk of failure of electrical contact between the metal layer M3 and the metal layer M4.

In this embodiment, the organic insulating layer 12 is covered by the inorganic insulating layer IL, the scraping of the organic insulating layer 12 can be suppressed. Since the organic insulating layer 12 reliably covers the side walls M3W of the metal layer M3, the aluminum layer is less likely to be exposed from the side walls M3W of the metal layer M3.

With this configuration, during the processing step of forming the lower electrodes LE1, LE2, and LE3, silver deposition near the metal layer M3 is suppressed, thereby making it possible to prevent the occurrence of failure of electrical contact between the metal layer M3 and the metal layer M4. Consequently, in this embodiment, a decrease in the reliability of the display device DSP can be suppressed.

Furthermore, in this embodiment, the rib layer 5 formed from an inorganic insulating material is in contact with the inorganic insulating layer 113 through the slit ILS and is firmly attached thereto.

With this configuration, the adhesion between the rib layer 5 and the substrate layer is improved, thereby making it possible to suppress the peeling of the rib layer 5.

Moreover, in the manufacturing method described with reference to FIGS. 7 to 13, the titanium layer located above the metal layer M3 is exposed to etching twice due to the etching of the inorganic insulating layer IL and the rib layer 5.

In such a case, the titanium layer of the metal layer M3 may disappear, and therefore there is a risk of exposing the aluminum layer. When the exposed aluminum layer oxidizes, the contact resistance between the metal layer M3 and the metal layer M4 increases, and therefore there is a possibility of causing failure of electrical contact between the metal layer M3 and the metal layer M4.

In contrast, in the manufacturing method described using FIGS. 14 to 18, the rib layer 5 and the inorganic insulating layer IL are etched continuously. With this configuration, the titanium layer of the metal layer M3 is exposed to etching only once, and therefore the titanium layer of the metal layer M3 is less likely to disappear. In other words, the aluminum layer of metal layer M3 is less likely to be exposed. Therefore, according to the manufacturing method described with reference to FIGS. 14 to 18, it is possible to more effectively suppress the occurrence of poor electrical contact between metal layer M3 and metal layer M4 compared to the manufacturing method described with reference to FIGS. 7 to 13.

As described above, according to the configuration of the present embodiment, it is possible to provide a display device DSP which can suppress a decrease in reliability. In addition, various other advantageous effects can be obtained from the present embodiment.

Note that the present embodiment discloses an example in which inorganic insulating layers IL adjacent to each other along the first direction X are spaced apart, but the inorganic insulating layers IL may not be spaced apart. In this case, the rib layer 5 formed of an inorganic insulating material is brought into contact with the inorganic insulating layer IL between each adjacent pair of pads PD.

Based on the display devices and the manufacturing methods described above as embodiments of the invention, a person having ordinary skill in the art may achieve display devices and manufacturing devices with arbitral design changes; however, as long as they fall within the scope and spirit of the present invention, all of such display devices are encompassed by the scope of the present invention. A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is

1. A display device comprising:
a substrate;
a first inorganic insulating layer disposed above the substrate and over an image display area that displays images and a peripheral area surrounding the image display area;
a first metal layer disposed above the first inorganic insulating layer in the peripheral area;
an organic insulating layer disposed in the image display area and the peripheral area, covering the peripheral portion of the first metal layer, and having a first aperture overlapping the first metal layer;
a second inorganic insulating layer covering the organic insulating layer and having a second aperture overlapping the first aperture; and
a third inorganic insulating layer disposed above the second inorganic insulating layer and having a third aperture overlapping the second aperture.

2. The display device of claim 1, wherein
the third inorganic insulating layer is formed from an inorganic insulating material different from that of the second inorganic insulating layer.

3. The display device of claim 2, wherein
the second inorganic insulating layer is formed of silicon nitride, and
the third inorganic insulating layer is formed of silicon nitride.

4. The display device of claim 1, further comprising:
a lower electrode disposed above the organic insulating layer in the display area,
wherein
the third inorganic insulating layer is disposed above the organic insulating layer and the lower electrode in the display area and has a pixel aperture overlapping the lower electrode, and
the second inorganic insulating layer is disposed between the organic insulating layer and the lower electrode in the display area.

5. The display device of claim 4, further comprising:
an organic layer that covers the lower electrode through the pixel aperture and emits light according to application of a voltage; and
an upper electrode that covers the organic layer.

6. The display device of claim 5, further comprising:
a partition including a lower portion disposed above the third inorganic insulating layer and an upper portion having end portions protruding from side surfaces of the lower portion, in the display area, and surrounding the pixel aperture.

7. The display device of claim 1, further comprising:
a second metal layer disposed above the first metal layer and electrically connected to the first metal layer through the first aperture, the second aperture, and the third aperture.

8. The display device of claim 7, further comprising:
a plurality of pads each including the first metal layer and the second metal layer,
wherein
the organic insulating layer has a slit formed between each adjacent pair of the pads.

9. The display device of claim 8, wherein
the third inorganic insulating layer is in contact with the first inorganic insulating layer between each adjacent pair of the pads.

10. The display device of claim 8, wherein
the second inorganic insulating layer is in contact with the first inorganic insulating layer between each adjacent pair of the pads.

11. The display device of claim 8, wherein
the second inorganic insulating layer is in contact with the first metal layer in the first aperture.

12. A method for manufacturing a display device, comprising:
forming a first metal layer above a first inorganic insulating layer disposed over a display area and a peripheral area surrounding the display area, in the peripheral area;
forming an organic insulating layer which covers the peripheral portion of the first metal layer, and includes a first aperture overlapping the first metal layer;
forming a second inorganic insulating layer which covers the organic insulating layer;
forming a third inorganic insulating layer above the second inorganic insulating layer; and
forming a second aperture overlapping the first aperture in the second inorganic insulating layer and a third aperture overlapping the second aperture in the third inorganic insulating layer by continuously etching the second inorganic insulating layer and the third inorganic insulating layer.

13. A method for manufacturing a display device, comprising:
forming a first metal layer above a first inorganic insulating layer disposed over a display area and a peripheral area surrounding the display area, in the peripheral area;
forming an organic insulating layer which covers the peripheral portion of the first metal layer, and includes a first aperture overlapping the first metal layer;
forming a second inorganic insulating layer which covers the organic insulating layer;
forming a second aperture which overlaps the first aperture by etching the second inorganic insulating layer;
forming a third inorganic insulating layer above the second inorganic insulating layer, after forming the second aperture; and
forming a third aperture which overlaps the second aperture by etching the third inorganic insulating layer.

14. The method of claim 12, further comprising:
forming a second metal layer which is in contact with the first metal layer through the first aperture, the second aperture, and the third aperture, above the first metal layer.

15. The method of claim 13, further comprising:
forming a second metal layer which is in contact with the first metal layer through the first aperture, the second aperture, and the third aperture, above the first metal layer.
